(19) United States
(12) Patent Application Publication
(10) Pub. No.: US 2013/0108065 A1
(43) Pub. Date: May 2, 2013

(54) METHODS FOR INVOKING TESTING USING REVERSIBLE CONNECTORS

(71) Applicants: Scott Mullins, Morgan Hill, CA (US); Alexei Kosut, Mountain View, CA (US); Brian J. Conner, San Jose, CA (US); Joseph R. Fisher, JR., San Jose, CA (US); Dustin J. Verhoeve, San Francisco, CA (US); Saket R. Vora, San Francisco, CA (US); Erturk D. Kocalar, Sunnyvale, CA (US); Casey Hardy, San Francisco, CA (US); Adriane S. Niehaus, San Jose, CA (US)

(72) Inventors: Scott Mullins, Morgan Hill, CA (US); Alexei Kosut, Mountain View, CA (US); Brian J. Conner, San Jose, CA (US); Joseph R. Fisher, JR., San Jose, CA (US); Dustin J. Verhoeve, San Francisco, CA (US); Saket R. Vora, San Francisco, CA (US); Erturk D. Kocalar, Sunnyvale, CA (US); Casey Hardy, San Francisco, CA (US); Adriane S. Niehaus, San Jose, CA (US)

(21) Appl. No.: 13/286,448

(22) Filed: Nov. 1, 2011

(51) Int. Cl. H04R 29/00; G01R 31/3187

(52) U.S. Cl. 381/58; 324/750.3; 714/727; 714/E11.001

(57) ABSTRACT

Electronic devices may be provided with audio circuits and controller circuitry configured to support test mode operations. A connector such as a reversible connector may be inserted into a mating device connector in an electronic device. The reversible connector may be connected to the device connector in either a normal orientation or a reversed orientation in which the reversible connector is rotated 180° with respect to the normal orientation. During test mode operations, a tester may be coupled to the device connector using the reversible connector. The tester may generate voltages, resistances, time-varying signals, or other input that directs the device to configure switching circuitry to support testing. Monitoring circuitry in the device may be used to detect input from the tester. In response to detected input from the tester, the switching circuitry may be adjusted to couple the controller to the device connector.

### BACKGROUND

This relates generally to electronic devices, and, more particularly, to testing electronic devices.

Electronic devices such as media players, portable computers, and cellular telephones are generally tested during manufacturing. Testing is often performed using procedures that are compliant with the IEEE 1149.1 standard. This type of testing, which is sometimes referred to as Joint Test Action Group (JTAG) testing, can be used to capture and analyze scan chain data and perform other debug procedures.

Challenges can arise with conventional JTAG testing procedures. In some situations, it is necessary to probe a printed circuit board within a device to perform tests or to make manufacturing changes to a printed circuit board once testing is complete. Other test procedures rely on device software that is susceptible to freezing.

It would therefore be desirable to be able to provide improved techniques for testing electronic devices.

### SUMMARY

An electronic device may be provided with audio circuitry and controller circuitry configured to support test mode operations. A connector such as a reversible connector may be inserted into a mating device connector in the electronic device. The reversible connector may be connected to the device connector in either a normal orientation or a reversed orientation in which the reversible connector is rotated 180° with respect to the normal orientation. The device connector may have six contacts surrounded by a ground. The reversible connector may have a ground that mates with the device connector ground and contacts that mate with some or all of the six contacts in the device connector.

During test mode operations, a tester may be coupled to the device connector using the reversible connector. The tester may generate voltages, resistances, time-varying signals, or other input that directs the device to configure switching circuitry to support testing. Monitoring circuitry in the device may be used to detect input from the tester. In response to detected input from the tester, the switching circuitry may be adjusted to couple the controller to the device connector. The controller may be used to perform test mode operations such as Joint Test Action Group testing operations. During normal operation, the switching circuitry can be configured to couple the audio circuitry or other circuitry to the device connector.

Further features of the invention, its nature and various advantages will be more apparent from the accompanying drawings and the following detailed description of the preferred embodiments.

### BRIEF DESCRIPTION OF THE DRAWINGS

FIG. 1 is a diagram of an illustrative system in which an electronic device and external equipment may be operated in accordance with an embodiment of the present invention.

FIG. 2 is a circuit diagram of illustrative circuitry of the type that may be used in the electronic device of FIG. 1 in accordance with an embodiment of the present invention.

FIG. 3 is a state diagram showing operations involved in monitoring whether a tester has directed an electronic device to enter test mode in accordance with an embodiment of the present invention.

FIG. 4 is a diagram of an illustrative connector that may be used in an electronic device of the type that may be placed in a test mode to perform testing in accordance with an embodiment of the present invention.

FIG. 5 is a diagram of an illustrative connector of the type that may be provided to external equipment for mating in a normal orientation with a connector of the type shown in FIG. 4 in accordance with an embodiment of the present invention.

FIG. 6 is diagram of the connector of FIG. 5 in a reversed orientation that is rotated 180° with respect to the normal orientation of FIG. 5 in accordance with an embodiment of the present invention.

FIG. 7 is a diagram of an illustrative tester that may be used in testing an electronic device in accordance with an embodiment of the present invention.

FIG. 8 is a diagram of illustrative monitor circuitry that may be used to compare signals on different contacts in a device connector in accordance with an embodiment of the present invention.

FIG. 9 is a diagram illustrative monitor circuitry that may be used to compare signals on contacts in a device connector to reference signals in accordance with an embodiment of the present invention.

FIG. 10 is a table showing how patterns of voltages may be provided to different contacts in a connector in a device in accordance with an embodiment of the present invention.

FIGS. 11 and 12 are graphs showing illustrative time-varying voltages that may be supplied to a connector in a device in accordance with an embodiment of the present invention.

FIG. 13 is a table showing patterns of resistances that may be applied across different pairs of contacts in a device connector in accordance with an embodiment of the present invention.

FIG. 14 is a flow chart of steps involved in controlling a device during testing in accordance with an embodiment of the present invention.

### DETAILED DESCRIPTION

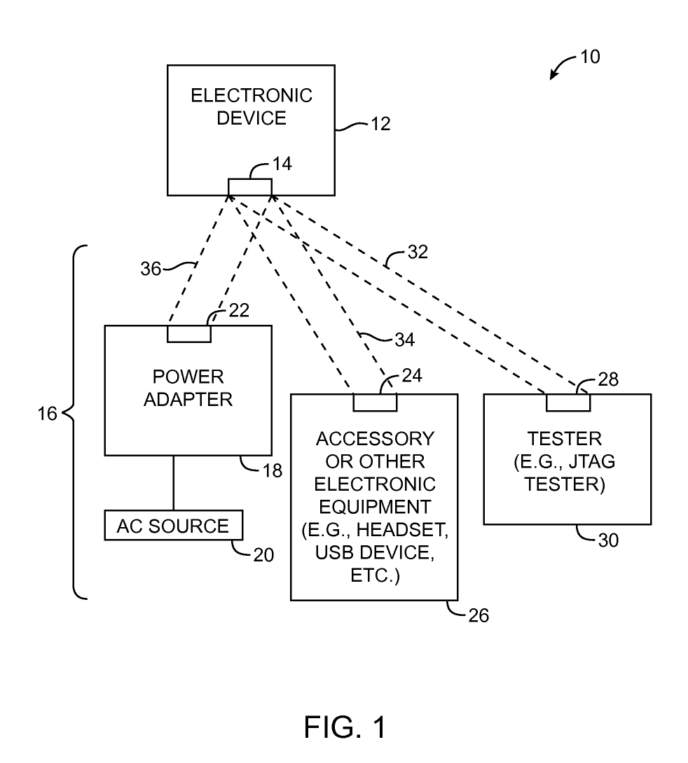

Electronic devices may be provided with circuitry that supports testing. An illustrative system environment for a device that has circuitry that supports testing is shown in FIG. 1. As shown in FIG. 1, system 10 may include an electronic device such as electronic device 12. Electronic device 12 may be a portable electronic device or other suitable electronic device. For example, electronic device 12 may be a laptop computer, a tablet computer, a somewhat smaller device such as a wrist-watch device, pendant device, headphone device, earpiece device, or other wearable or miniature device, a cellular telephone, a media player, larger devices such as desktop computers, computers integrated into computer monitors, or other electronic devices.

Device 12 may include a connector such as connector 14. Connector 14 may have two contacts, three contacts, four contacts, five contacts, six contacts, six or more contacts, six or fewer contacts (e.g., a ground contact and five or fewer contacts), seven contacts, seven or more contacts, seven or fewer contacts (e.g., a ground contact and six or fewer contacts), thirty contacts, or any other suitable number of contacts.

Connector 14 may be coupled to different types of external equipment. As shown in FIG. 1, external equipment 16 of the type that may be connected to device 12 may include power supplies such as power adapter 18, accessories such as accessory 26, and testers such as tester 30 (as examples).

Power adapter 18 may convert alternating current power from alternating current (AC) source 20 into direct current (DC) signals at connector 22. When it is desired to charge a battery in device 12 or to otherwise provide power to device 12, power adapter connector 22 may be connected to mating electronic device connector 14, as illustrated by path 36.

Accessory 26 may include a connector such as connector 24 that mates with connector 14. Accessory 26 may be a mono or stereo headset with a microphone, a mono or stereo headset without a microphone, a charging station, an external set of speakers, a computer (e.g., a laptop or desktop computer that is being used to provide power to device 12 and/or that is being used to synchronize data with device 12), or other suitable accessories or external equipment. When it is desired to use accessory 26 with device 12, accessory connector 24 may be plugged into connector 14 of electronic device 12, as indicated by path 34.

Testing may be performed using tester 30. Tester 30 may be a Joint Test Action Group (JTAG) tester or test equipment that supports other testing protocols. JTAG testers sometimes use four or five pin interfaces (e.g., interfaces that include pins such as a JTAG test data input pin TDI, a JTAG test data output pin TDO, a JTAG clock pin TCK, a JTAG state machine control pin TMS, and, if desired, a reset pin). In some test environments, it may be desirable to minimize pin counts, so protocols such as the Serial Wire Debug (SWB) protocol have been developed that support testing over two pins (e.g., using a SWDIO data pin and a clock pin SWCLK). Serial Wire Debug interfaces can be used to support JTAG testing. Illustrative configurations in which tester 30 is a tester of the type that may support JTAG and/or Serial Wire Debug testing are sometimes described herein as an example. In general, however, tester 30 may support any suitable test protocols. As shown by path 32, test connector 28 of tester 30 may be mated with connector 14 of electronic device 12 when it is desired to test device 12.

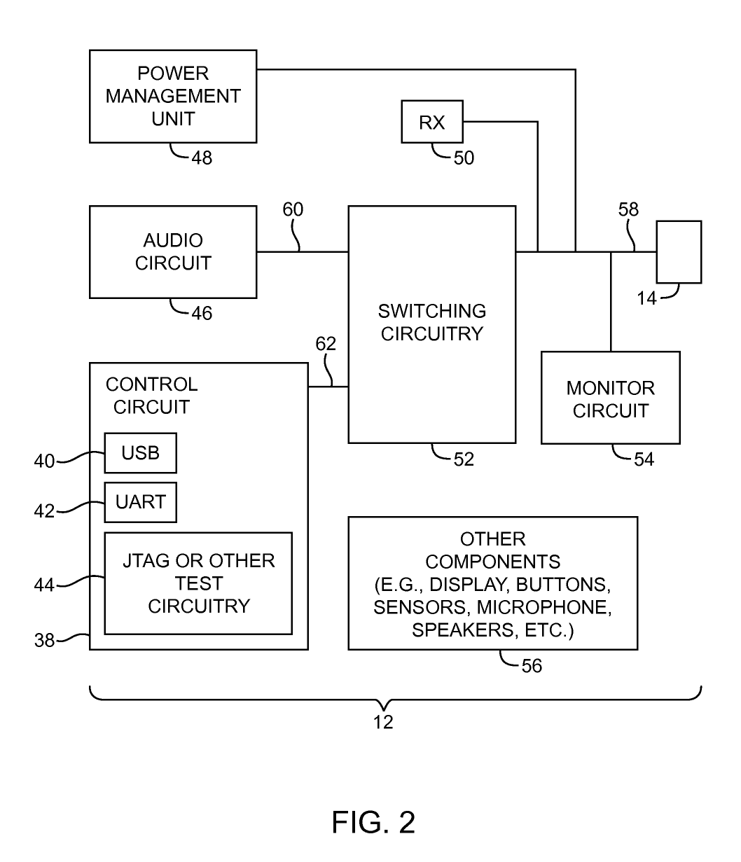

Illustrative circuitry that may be provided in electronic device 12 is shown in FIG. 2. As shown in FIG. 2, a path such as path 58 may be coupled to connector 14. Path 58 may include conductive traces on a printed circuit board or other substrate. Components such as integrated circuits, switches, sensors, and other devices may be mounted on the substrate. The traces or other conductive lines in path 58 may each be connected to a respective contact in connector 14. If, for example, connector 14 contains four, five, six, or seven contacts, each of the four, five, six, or seven contacts may be connected to a respective line in path 58.

Device 12 may use a monitor circuit such as monitor circuit 54 to monitor the status of connector 14. For example, monitor circuit 54 may monitor the contacts of connector 14 for the presence of a signal or connector characteristic that indicates that device 12 should enter a testing mode (e.g., a JTAG mode).

Switching circuitry 52 may be used to selectively couple the lines in communications path 58 to lines such as lines in paths 60 and 62. For example, during normal operation of device 12 by a user, switching circuitry 52 may be configured to route signals from connector 14 to audio circuit 46 using two or more lines in path 60. During test mode operations, switching circuitry 52 may be configured to route signals from connector 14 to test module 44 of control circuitry 38 via two or more lines in path 62.

Audio circuit 46 may be, for example, an audio integrated circuit that handles analog and/or digital audio signals. Functions such as media playback, microphone signal amplification, noise cancellation, digital-to-analog and analog-to-digital conversion, equalization, volume control, pin assignment swapping (e.g., to accommodate headsets in which the microphone and ground terminals are reversed), and other control and audio processing features may be handled by audio circuit 46. In some contexts, audio circuit 46 may be referred to as a codec. Non-audio functions may, if desired, be integrated into audio circuit 46 or provided using other circuits in device 12.

Control circuit 38 may be implemented using one or more integrated circuits. Control circuit 38 may, for example, be implemented using an integrated circuit of the type that is sometimes referred to as a system-on-a-chip (SOC) integrated circuit. System-on-a-chip integrated circuits generally include a processor and other circuits. Control circuit 38 may include memory or may be coupled to external storage (e.g., memory in components 56).

Control circuit 38 may include processing circuits such as one or more testing and communications modules. As an example, control circuit 38 may include a communications module such as Universal Serial Bus (USB) module 40, a communications module such as Universal Asynchronous Receiver Transmitter (UART) module 42, and other communications circuits. Control circuit 38 may include circuitry that is configured to support test mode operations such as testing circuitry 44. Testing circuitry 44 may support test protocols such as four or five wire JTAG protocols and/or protocols in which JTAG data is conveyed use a two-wire test interface such as a Serial Wire Debug interface.

Power management unit 48 may be used to handle operations associated with receiving external power through connector 14. For example, when power adapter 18 (FIG. 1) is coupled to connector 14, power management unit 48 may be used in routing the power from power adapter 18 to a battery within device 12 when the battery is in need of charging. Power management unit 48 may also route power to internal circuitry within device 12 when it is desired to power device 12 directly from externally supplied DC signals.

Accessories 26 (FIG. 1) such as headsets may include antennas. For example, wiring within a headset may serve as a frequency modulation (FM) antenna for device 12. Receiver circuitry 50 within device 12 can receive FM signals from the antenna via connector 14 and path 58.

Device 12 may contain other components 56. Components 56 may include one or more displays, status indicator lights, buttons, sensors, microphones, speakers, a battery, amplifiers, radio-frequency transceiver circuits, microprocessors, microcontrollers, volatile memory (e.g., dynamic random-access memory, static random-access memory, etc.), non-volatile memory (e.g., flash memory or other solid state storage), hard drives, application-specific integrated circuits, and other electrical components. These components may be interconnected with the other components shown in FIG. 2. For example, one or more rigid printed circuit boards (e.g., fiberglass-filled epoxy printed circuit boards) and/or flexible printed circuits (e.g., flex circuits formed from patterned conductive traces on flexible sheets of polyimide or other polymers) may serve as substrates onto which the components of FIG. 2 may be mounted. The storage and processing circuitry in device 12 such as the non-volatile and volatile memory in device 12, control circuit 38, microprocessor circuitry, and processing circuitry in application-specific integrated circuits in device 12 form control circuitry that can be used in running software for device 12, controlling the operation of switching circuitry 52 and other components 56 in device 12, etc.

To ensure that device 12 enters a JTAG test mode or other desired testing mode, device 12 may be provided with external input. The external input may take the form of insertion of a predefined connector into connector 14, signals that are supplied to connector 14 by tester 30, and/or other suitable input for directing device 12 to enter a test mode of operation.

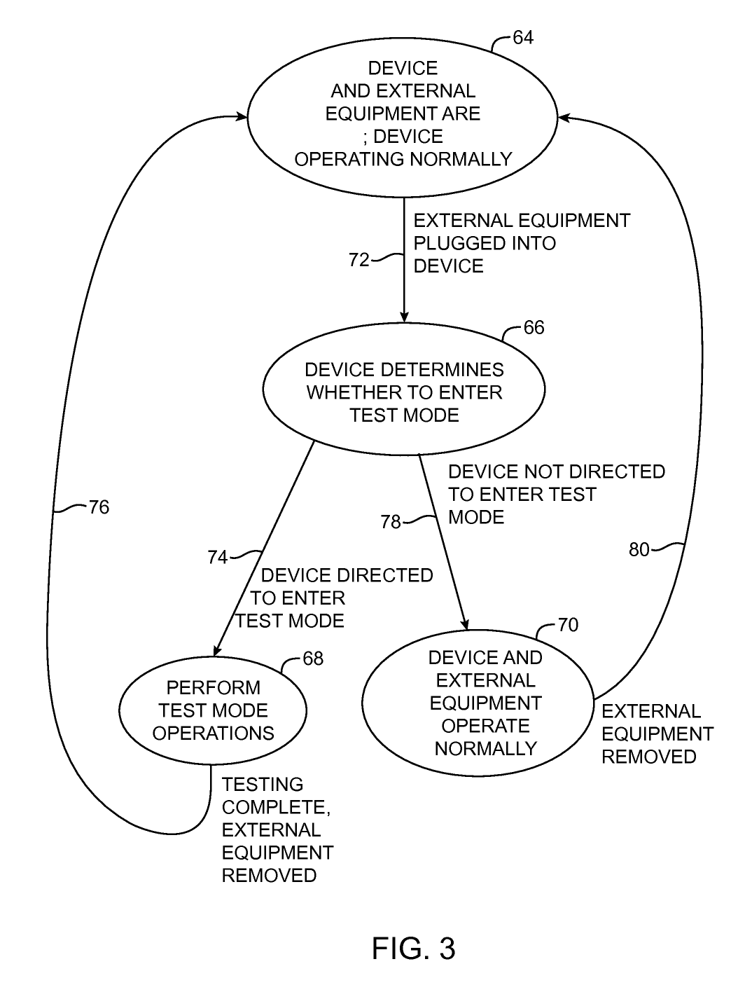

A state diagram showing operations involved in using device 12 in a system environment such as system 10 of FIG. 1 is shown in FIG. 3. During the operations of state 64, device 12 is disconnected from external equipment 16. In particular, device 12 is not connected to any accessories 26, device 12 is not connected to power adapter 18, and device 12 is not connected to tester 30.

As indicated by line 72, when a piece of external equipment 16 is plugged into device 10, device 12 may perform operations to determine whether to enter test mode (state 66). These operations may include, for example, using monitor circuit 54 to measure signals on the contacts of connector 14. Signal measurements may be made, for example, to compare the signals on the contacts to reference signals (e.g., to compare signal voltages to reference voltages), to compare the magnitudes of the signals to each other (e.g., to compare signal voltages on one or more contacts to signal voltages on one or more other contacts), to compute resistances, to evaluate the states of sensors that monitor whether a connector is plugged into connector 14, etc.

In response to a determination by device 12 that device 12 is not being instructed to enter test mode (i.e., because the external equipment that was connected to device 12 was a power adapter or other accessory and not a tester), device 12 may transition to state 70, as indicated by line 78. During the operations of state 70, device 12 and the external equipment that is connected to device 12 (e.g., power adapter 18 or other accessories such as accessory 26) may be operated normally. Once the external equipment is removed, device 12 may transition back to state 64, as indicated by line 80.

In response to a determination by device 12 that device 12 is being instructed to enter test mode (i.e., because the external equipment that was coupled to device 12 was a tester such as tester 30), device 12 may transition to state 68 (test mode), as indicated by line 74. During state 68, test circuitry 44 or other circuitry in control circuitry 38 that is configured to support test mode operations may be activated and used for handling test operations. For example, JTAG circuitry may be used to perform boundary scan test operations, may be used in conveying test data to tester 30, and may be used in performing other test operations for testing whether device 12 is operating satisfactorily. If errors are identified, a test operator may be alerted (e.g., by displaying an alert message on tester 30). Debugging operations may be performed in which test data captured by circuitry 44 is transmitted to tester 30 for analysis. Tester 30 may also direct the components of device 12 to perform various actions (e.g., adjusting integrated circuit settings, etc.) and may evaluate the ability of device 12 to execute these actions.

Once testing has been completed, tester 30 may be disconnected from connector 14 and, as indicated by line 76, device 12 may be operated while being decoupled from external equipment (state 64).

Switching circuitry 52 may contain electronic switches that are controlled by control signals from control circuitry in device 12 (e.g., control circuit 38 and/or other storage and processing circuitry in device 12). Switches within switching circuitry 52 may be based on transmission gates (e.g., gates based on metal-oxide-semiconductor transistors) or other electrically controllable switch technologies.

There may be any suitable number of switches in switching circuitry 52 (e.g., one or more, two or more, five or more, ten or more, etc.). The number of switches that are used in switching circuitry 52 may be selected to provide a desired amount routing flexibility for signals within device 12. For example, if it is desired to be able to route a set of signals from connector 14 to internal circuitry in a normal or reversed configuration, switching circuitry 52 may be provided with sufficient switching resources (e.g., cross-bar switches) to perform this type of signal switching.

As another example, if it is desired to route signals from a contact in connector 14 to several possible destinations such as a pin in audio circuit 46, a pin associated with USB module 40, a pin associated with UART module 42, and a pin associated with test circuitry 44, switching circuitry 52 may be provided with switches for forming a multiplexing circuit that is capable of selecting which of these various paths should be formed in device 12. Configurations for switching circuitry 52 that include relatively more switches may be used to provide enhanced amounts of interconnection flexibility, whereas configurations for switching circuitry 52 that include relatively fewer switches may be used to conserve device resources.

Connector 14 and the mating connectors associated with external equipment 16 may be based on a connector format such as a 30-pin connector format that has a particular allowed orientation. Connectors of this type can be mated in the allowed (normal) orientation, but cannot be reversed. For example, a 30-pin plug will generally only fit into a 30-pin jack when properly oriented. If the plug is flipped 180° with respect to the proper orientation (i.e., if the orientation of the plug is reversed), the plug will not fit into the jack.

If desired, connectors such as connector 14 and the mating connectors associated with external equipment 16 may be formed using reversible connectors. With a reversible connector design, a plug or other connector associated with external equipment 16 may be inserted into connector 14 in two different orientations (sometimes referred to as normal and 180° reversed orientations).

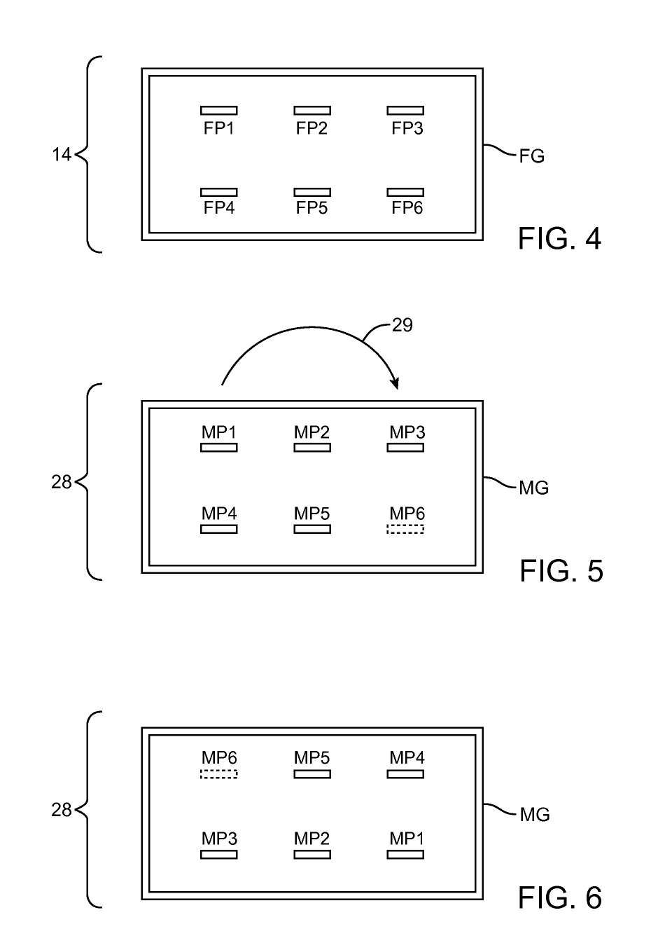

A reversible connector of the type that may be used for connector 14 and the mating connectors of equipment 16 may have any suitable number of contacts (e.g., two or more, three or more, four or more, five or more, six or more, seven or more, or eight or more). An illustrative configuration in which connector 14 has been implemented using six contacts FP1, FP2, FP3, FP4, FP5, and FP6 surrounded by ground contact FG is shown in FIG. 4.

The connectors in equipment 16 that mate with connector 14 such as connector 28 may have configurations of the type shown in FIGS. 5 and 6. Connector 28 is shown in a normal (not-reversed) configuration in the end view of FIG. 5. When rotated 180° about its longitudinal axis (i.e., in direction 29 of FIG. 5) connector 28 of FIG. 5 may be moved from its normal orientation with respect to connector 14 to its reversed orientation with respect to connector 14 (FIG. 6).

As shown in FIG. 5, connector 28 may have a ground contact such as ground contact MG that mates with ground contact FG of connector 14 when connector 28 is inserted into connector 14. Contacts MP2, MP3, MP4, and MP5 may, if desired, be pins that are used for receiving and transmitting analog and/or digital data signals (e.g., analog or digital audio signals, Universal Serial Bus digital data signals and other digital data signals, analog or digital control signals or non-audio signals, etc.). Contact MP1 may be used to carry power or other signals. For example, contact MP1 may correspond to a positive power supply line that carries a positive voltage with respect to a 0 volt ground voltage on ground MG. Optional contact MP6 may be used for data or power and may, if desired, be omitted.

If desired, other configurations for the pins in connector 28 may be used. The use of contacts MP1 and MG to carry power and the use of one or more of contacts MP2, MP3, MP4, and MP5 to carry non-power signals is merely illustrative. In general, contacts MP1, MP2, MP3, MP4, MP5, MP6, and MG may each be used to carry any suitable type of signals (analog, digital, data, power, etc.).

Connector 28 may be associated with tester 30. When connector 28 is mated with connector 14 in the normal orientation of FIG. 5, contact MP1 may mate with contact FP1, contact MP2 may mate with contact FP2, contact MP3 may mate with contact FP3, contact MP4 may mate with contact FP4, contact MP5 may mate with contact FP5, and optional contact MP6 may (if present) mate with contact FP6. When connector 28 is mated with connector 14 in the reversed orientation of FIG. 6, contact MP6 may, if present, mate with contact FP1, contact MP5 may mate with contact FP2, contact MP4 may mate with contact FP3, contact MP3 may mate with contact FP4, contact MP2 may mate with contact FP5, and contact MP1 may mate with contact FP6.

Device 12 may detect the orientation of connector 28 by monitoring signals on the contacts of connector 14. As an example, in a configuration of the type in which contact MP6 is not present, the orientation of connector 28 may be detected by comparing the voltages on pins FP1 and FP6. When connector 28 is connected in the normal orientation of FIG. 5, a positive voltage (i.e., the positive power supply voltage carried by contact MP1) will be detected on contact FP1 whereas contact FP6 will be floating. When connector 28 is connected in the reversed orientation of FIG. 6, a positive voltage (i.e., the positive power supply voltage carried by contact MP1) will be detected on contact FP6 wile contact FP1 is floating.

Switching circuitry 52 may, if desired, contain an electrically configurable crossbar switch or other suitable switching circuitry that accommodates coupling between connector 28 and connector 14 in both the normal and reversed configurations of FIGS. 5 and 6. When connector 28 is plugged into connector 14 in the orientation of FIG. 5, the switching circuitry may, for example, have a first configuration. When connector 28 is plugged into connector 14 in the reversed orientation of FIG. 6, the crossbar switch or other switching circuitry 52 in device 12 may be placed in a second (reversed) configuration to route signals within device 12 in the same way that the signals are routed when connector 28 is in its normal orientation (i.e., so that signals from MP1 are routed to FP1, so that signals from MP2 are routed to FP2, etc.). The need for crossbar switches may, if desired, be reduced or eliminated by using pin assignments that allow device 12 to function properly regardless of the orientation of connector 28.

Reversible connectors of the type shown in FIGS. 5 and 6 may be used for connectors 22 and 24 (FIG. 1). If desired, reversible connectors such as connector 14 of FIG. 4 and connector 28 of FIGS. 5 and 6 may have different number of contacts. The examples of FIGS. 4, 5, and 6 are merely illustrative.

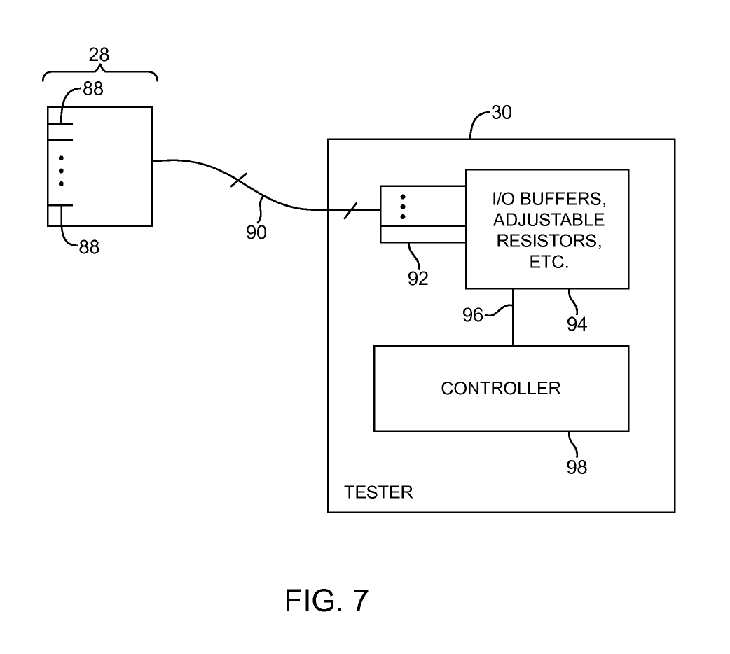

FIG. 7 is a circuit diagram showing an illustrative configuration that may be used for tester 30 of FIG. 1. As shown in FIG. 7, tester 30 may include control circuitry such as controller 98. Controller 98 may be based on one or more microprocessors, one or more microcontrollers, one or more application-specific integrated circuits, or other control circuitry.

Controller 98 may be coupled to control circuitry such as input-output circuitry 94 via paths such as path 96. Input-output circuitry 94 may include input-output buffers (e.g., output drivers capable of generating voltages at adjustable and/or fixed voltages of desired magnitudes), adjustable resistors, adjustable current sources, or other input-output circuitry. Conductive paths 92 (e.g., traces on a printed circuit board or other substrates) may be used to couple output signals from output buffers, adjustable resistors, and other input-output circuitry 94 to respective lines in path 90. Each of lines 92 may be coupled between a respective input-output pin associated with circuitry 94 and a conductive path such as a conductive wire in path 90. Path 90 may be implemented using a cable containing wires that are connected to respective contacts 88 in a pigtailed connector (connector 28), as shown in FIG. 7. There may be any suitable number of contacts 88 in connector 28. For example, connector 28 may include contacts such as contacts MP1, MP2, MP3, MP3, MP5, optional contact MP6, and ground contact MG of FIG. 5.

During testing, control circuitry in tester 30 such as controller 98 and input-output circuitry 94 may provide commands to a device under test that direct the device under test to enter test mode. For example, tester 30 may use controller 98 and input-output circuitry 94 to produce a particular pattern of voltages (or resistances) at contacts 88. These signals may be detected by monitoring circuitry in the device under test.

FIG. 8 shows how monitoring circuitry 54 of device 12 may contain circuitry for comparing the voltages on the contacts of connector 14. Lines 200 in FIG. 8 may be coupled to a pair of respective contacts in connector 14. Comparator 202 may compare the voltages on the signals on lines 200 and may supply a corresponding output on output line 204. The signal on output 204 may, for example, be a logic high value when the upper line 200 has a higher voltage than the lower line 200 in FIG. 8 and may have a logic low value when the upper line 200 has a lower voltage than the lower line 200 in FIG. 8. Comparators such as comparator 202 may be used to compare the voltages on any two of the contacts in connector 14. Monitor circuitry 54 may have one comparator such as comparator 202, two comparators such as comparator 202, or more than two comparators such as comparator 202.

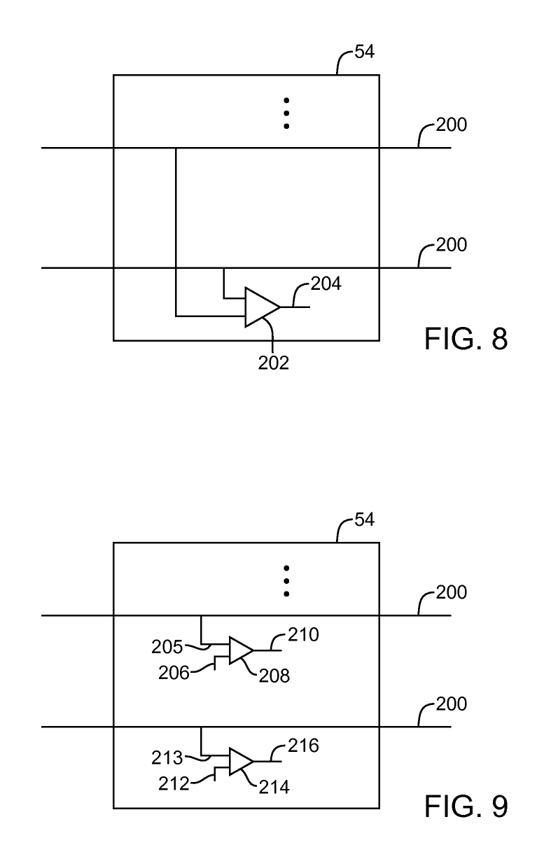

If desired, monitoring circuitry 54 may have one or more comparators that compare signal voltages on contacts in connector 14 to reference voltages. This type of configuration is shown in FIG. 9. In the FIG. 9 example, the upper one of lines 200 (which may be connected to a first contact in connector 14) may be connected to a first input of comparator 208 via path 205 while a second input of comparator 208 may receive a reference voltage on path 206. Comparator 208 may compare the voltages on paths 205 and 206 and may produce a corresponding high or low output signal on output 208. Comparator 214 may compare the voltage on the lower one of lines 200 to a reference. In particular, comparator 214 may receive the voltage on the lower one of lines 200 via input 213 and may receive a reference voltage on input 212. Comparator 214 may compare the voltages on inputs 213 and 212 and may produce a corresponding high or low logic output on output path 216. Additional comparators may be used to perform additional reference voltage comparisons if desired.

In general, monitor circuit 54 may have any suitable circuitry for monitoring signal attributes on lines 200 (and the associated contacts in connector 14). Monitor circuit 54 may, for example, have one or more circuits for measuring the resistance between respective contacts, may have one or more circuits for comparing a voltage magnitude on one contact to a voltage magnitude on another contact, may have one or more circuits for comparing signal magnitudes on different contacts to each other, may have circuitry for measuring time-varying signals, etc.

During normal operation when one of connectors 22 or 24 is coupled to connector 14, device 12 may operate normally (e.g., using audio circuit 46 or other circuitry to convey signals to contacts in connector 14, etc.). When it is desired to place device 12 into test mode (e.g., JTAG test mode), tester 30 may supply device 12 with suitable input via reversible connector 28 and connector 14. Device 12 may use monitor circuit 54 to measure voltages, currents, resistances, time-varying signals, or other suitable input associated with connector 14. For example, monitor circuit 54 may detect when tester 30 (FIG. 7) has placed a predetermined voltage or pattern of voltages on one or more of the contacts of connector 14 or has otherwise directed device 12 to enter test mode. In response to detection of different voltages on the contacts of connector 14 or other input, device 12 can be placed in different respective states.

As an example, when tester 30 desires to place device 12 in test mode, tester 30 can place a predetermined voltage on one of the contacts of connector 12. In response to detection of the predetermined voltage or voltages on the contacts, device 12 can be placed in test mode (e.g., using JTAG or other test circuitry 44 to perform tests and communicate with tester 30).

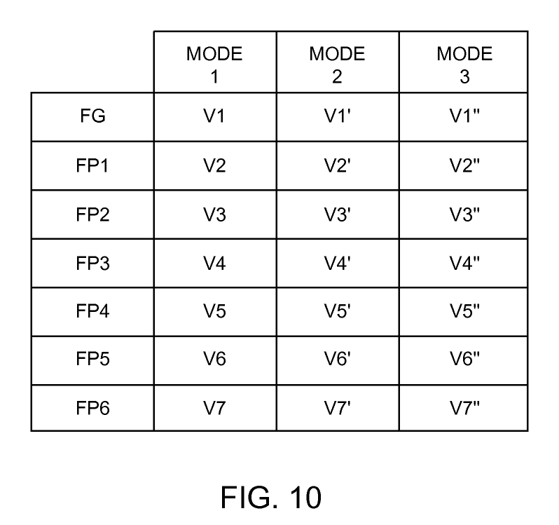

Consider, as an example, the use of tester 30 to place a pattern of one or more voltages on the contacts of connector 14 and connector 28 to control the operating mode of device 12. FIG. 10 is a table illustrating how patterns of voltages may be associated with different operating modes. In the example of FIG. 10, connector 14 is a connector of the type shown in FIG. 4 and has associated contacts FG, FP1, FP2, FP3, FP4, FP5, and FP6 (e.g., six contacts surrounded by ground FG). Monitor circuit 54 may measure the voltage on each of contacts these contacts and/or may compare relative voltages on one or more different pairs of these contacts (i.e., a pattern of voltages may be supplied to two or more of the contacts, to three or more of the contacts, to four or more of the contacts, to five or more of the contacts, or to all six of contacts FP1, FP2, FP3, FP4, FP5, and FP6 and ground FG).

When the pattern of voltages shown in the “mode 1” column of the table of FIG. 10 is provided to connector 14 (i.e., when voltage V1 is provided to contact FG, voltage V2 is provided to contact FP1, voltage V3 is provided to contact FP2, voltage V4 is provided to contact FP3, voltage V5 is provided to contact FP4, voltage V6 is provided to contact FP5, and voltage V7 is provided to optional contact FP6), device 12 may be placed in a first mode of operation (e.g., “mode 1”). When the pattern of voltages V1′, V2′, V3′, V4′, V5′, V6′, and V7′ associated with the “mode 2” column of the FIG. 10 table is provided to connector 14, device 12 may be placed in a second mode of operation (e.g., “mode 2”). When the pattern of voltages V1″, V2″, V3″, V4″, V5″, V6″, and V7″ associated with the “mode 3” column of the FIG. 10 table is provided to connector 14, device 12 may be placed in a third mode of operation (e.g., “mode 3”), etc. Voltages V1, V2, V3, V4, V5, V6, V7 V1′, V2′, V3′, V4′, V5′, V6′, V7′, V1″, V2″, V3″, V4″, V5″, V6″, and V7″ may have any suitable values ranging from 0 volts to 5 volts (as an example).

If desired, fewer voltages may be supplied to the contacts of connector 14 (e.g., one given voltage, two different voltages, a pattern of at least two different voltages, a pattern of at least three different voltages, or other patterns in which some of the voltages of FIG. 10 are floating). The arrangement of FIG. 10 is merely illustrative.

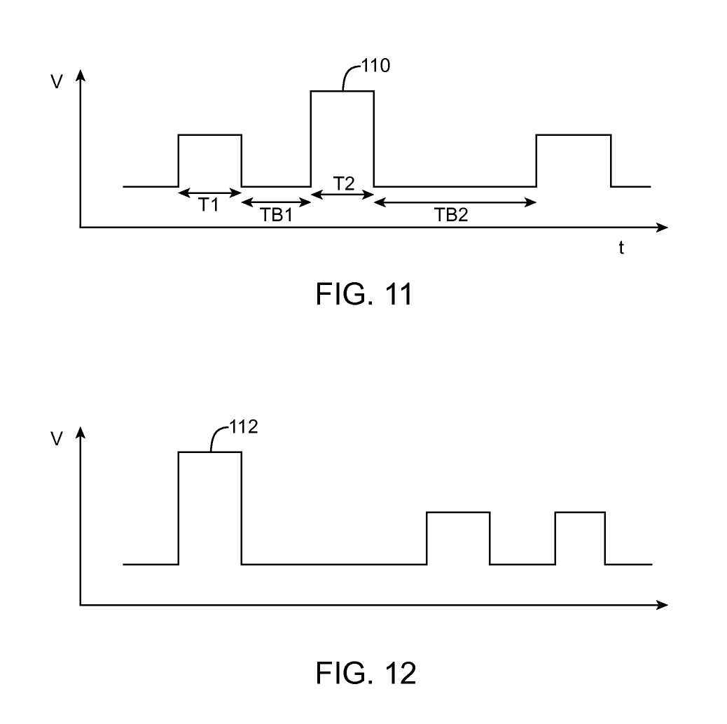

If desired, tester 30 may use controller 98 and input-output circuitry 94 or other control circuitry to generate time-varying signals on the contacts of connector 28. Monitor circuit 54 of device 12 may detect these time-varying signals on the mating contacts of connector 14 and may direct device 12 to respond accordingly. Curve 110 in the graph of FIG. 11 shows an illustrative time-varying control signal that tester 28 may supply to one of the contacts of connector 14 to place device 12 in a test mode or other desired mode of operation. As shown in FIG. 11, curve 110 may have pulses with different maximum voltages. The pulse may have differing pulse widths (e.g., time periods T1 and T2 for the illustrative first and second pulses in FIG. 11). The pulses may also be separated by varying amounts of time (e.g., the first and second pulses may be separated by time period TB1, the second and third pulses in the signal of curve 110 may be separated by time period TB2, etc.). The attributes of the signal produced by tester 30 may be used in directing device 12 to enter a desired mode of operation. For example, attributes such as signal magnitude, pulse width, pulse spacing, and other attributes of signal 110 may be combined to serve as a code that allows tester 30 to inform device 12 of a desired operating mode. If desired, pulses in a coded signal may have identical magnitudes and/or identical widths and/or non-square shapes). The example of FIG. 11 is merely illustrative.

Curve 112 of FIG. 12 shows how a different pattern of pulses with different magnitude and/or timing attributes may be supplied to device 12 by tester 30 when it is desired to place device 12 in a different mode of operation. Time varying signals such as the illustrative signals of FIGS. 11 and 12 may be applied to a single contact in connector 14 (e.g., the microphone contact or other contact) or multiple time-varying and/or fixed signals can be applied to multiple contacts 102. As an example, a single such as signal 110 of FIG. 11 may be applied to a first one of contacts 102 while a signal such as signal 112 of FIG. 12 is being applied to a second one of contacts 102. By using different combinations of signals, tester 30 can produce additional codes that are used to place device 12 in different respective modes of operation (as an example).

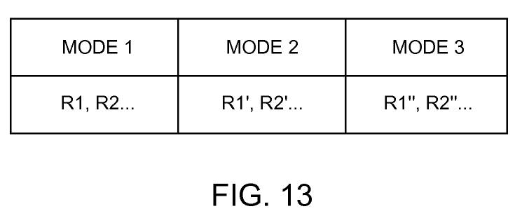

If desired, tester 30 may use controller 98 and input-output circuitry 94 to impose patterns of one or more different resistances, two or more different resistances, or other suitable number of different resistances across different respective pairs of contacts in connector 14 to place device 12 into desired modes of operation. As shown in FIG. 13, for example, tester 30 may place a resistance R1 across a first pair of terminals (e.g., FP1 and FP2) in connector 14, a resistance R2 across a second pair of terminals in connector 14, etc. In response, monitor circuit 54 may detect this pattern of resistances (or any suitable subset of these resistances) and the control circuitry of device 12 may be directed to enter a desired mode of operation. As shown in the columns of the table of FIG. 13, adjustable resistors or other circuitry of input-output circuitry 94 (FIG. 7) may be used in creating different patterns of resistances across the contacts in connector 28 (and therefore different corresponding patterns of resistances across the contacts in connector 14) to place device 12 in different modes of operation (e.g., mode 2, mode 3, etc.).

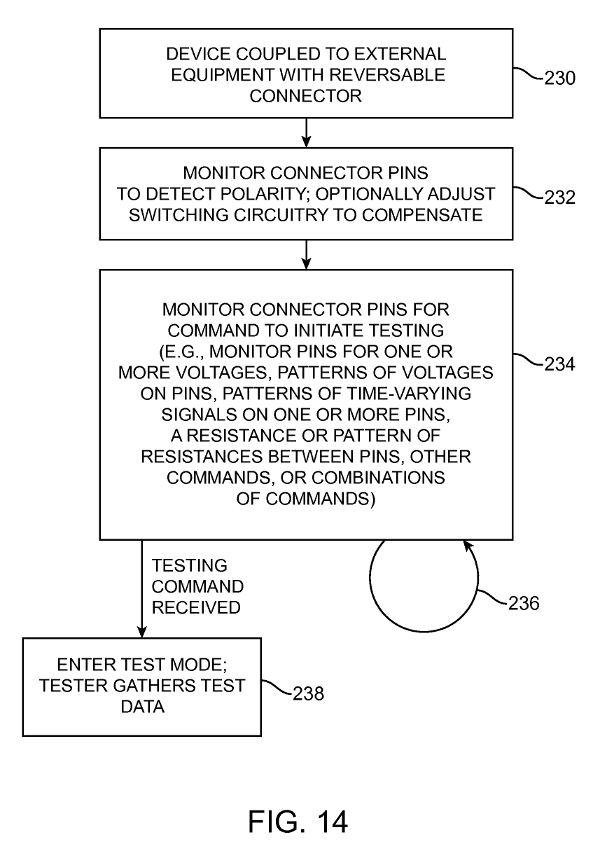

FIG. 14 is a flow chart of illustrative steps involved in operating devices such as device 12 of system 10 (FIG. 1). Initially, device 12 may be disconnected from any external equipment 16. At step 230, device 12 may be coupled to external equipment 16. For example, connector 22 of power adapter 18, connector 24 of accessory 26, or connector 28 of tester 30 may be connected to connector 14 of device 12.

At step 232, device 12 may, if desired, use monitor circuitry 54 to determine the orientation of connector 28 in connector 14 (i.e., whether connector 28 is connected to connector 14 in a normal configuration of the type described in connection with FIG. 5 or a reversed configuration of the type described in connection with FIG. 6). To determine the orientation of connector 28, monitor circuitry 54 may, for example, compare the voltages on a pair of contacts, may compare the voltage on one contact to a reference voltage, or may make other signal measurements). In response to determining that the polarity of connector 28 is reversed, the control circuitry of device 12 may, if desired, configure switching circuitry 52 to compensate for the connector reversal. Connector reversal scenarios may also be accommodated by transmitting signals over the contacts in connectors 28 and 14 using a pin assignment scheme that is immune to connector reversals (e.g., sending differential data signals over a pair of contacts such as contacts MP2 and MP5, so that data is properly transmitted and received regardless of the orientation in which connector 28 is connected to connector 14).

At step 232, device 12 may use monitor circuit 54 to monitor signals on the contacts of connector 14 to determine whether tester 30 is issuing a command to place device 12 in test mode. Monitor circuit 54 may, for example, monitor one or more of the contacts in connector 14 to detect voltage levels, resistances, time-varying signals, patterns of signals on multiple contacts, signals with particular values on a single one of the contacts, etc.

If the signals that monitor circuit 54 detects on one or more contacts of connector 14 indicate that device 12 should be operated normally (e.g., in a non-test mode), device 12 may be operated normally while monitor circuit 54 continues to monitor the status of contacts 102 (e.g., to detect voltages, to detect resistances, to detect time-varying signals, etc.), as indicated by line 236. During these operations, switching circuitry 52 may, as an example, have a normal configuration such as a configuration that couples audio circuit 46 (FIG. 2) or other non-testing circuitry in device 12 to connector 14.

In response to detection of a particular signal or pattern of signals that serve as commands to device 12 to enter test mode (e.g., a predetermined voltage on one contact, a predetermined pattern of voltages on multiple contacts, a resistance or resistances associated with one or more pairs of contacts, a predetermined time-varying signal, or other signals), device 12 may enter test mode (step 238). During test mode operations, switching circuitry 52 may be configured to support test operations and testing circuitry may be activated. For example, path 62 may be coupled to path 58 using switching circuitry 52 and JTAG or other testing circuitry 44 may be used to perform test mode operations.

The foregoing is merely illustrative of the principles of this invention and various modifications can be made by those skilled in the art without departing from the scope and spirit of the invention.

What is claimed is:

1. An electronic device, comprising:
a first circuit;
a second circuit, wherein the second circuit comprises test circuitry configured to support test mode operations;
a device connector that is configured to receive a reversible connector of a tester;
switching circuitry coupled between the first and second circuits and the device connector, wherein the switching circuitry is configured to route signals from the device connector to the first circuit during normal operation and is configured to route signals from the device connector to the second circuit during the test mode operations; and
control circuitry configured to monitor at least one contact in the device connector for at least one signal from the tester, wherein the control circuitry is configured to adjust the switching circuitry in response to detection of the at least one signal from the tester.

2. The electronic device defined in claim 1 wherein the device connector comprises at least six contacts and a ground and is configured to mate with the reversible connector in a normal orientation and a reversed orientation.

3. The electronic device defined in claim 2 wherein the ground in the device connector surrounds the six contacts and wherein the six contacts that are surrounded by the ground are the only contacts surrounded by the ground.

4. The electronic device defined in claim 3 wherein the first circuit comprises an audio circuit and wherein the second circuit comprises circuitry configured to perform Joint Test Action Group test operations.

5. The electronic device defined in claim 1 wherein the at least one signal from the tester comprises a predetermined voltage and wherein the control circuitry is configured to adjust the switching circuitry in response to detection of the predetermined voltage.

6. The electronic device defined in claim 5 wherein the second circuit comprises circuitry configured to perform Joint Test Action Group test operations.

7. The electronic device defined in claim 6 wherein the first circuit comprises an audio circuit.

8. The electronic device defined in claim 1 wherein the at least one signal from the tester comprises a time-varying voltage and wherein the control circuitry is configured to adjust the switching circuitry in response to detection of the time-varying voltage.

9. The electronic device defined in claim 8 wherein the time-varying voltage includes at least two signal pulses, wherein the first circuit comprises an audio circuit, and wherein the second circuit comprises circuitry configured to perform Joint Test Action Group test operations.

10. The electronic device defined in claim 1 wherein the device connector comprises six contacts surrounded by a ground and wherein the control circuitry is configured to adjust the switching circuitry in response to detection of a pattern of different voltages on at least two contacts in the device connector.

11. The electronic device defined in claim 10 wherein the second circuit comprises circuitry configured to perform Joint Test Action Group test operations.

12. The electronic device defined in claim 11 wherein the first circuit comprises an audio circuit.

13. The electronic device defined in claim 1 wherein the control circuitry is configured to adjust the switching circuitry in response to detection of a predetermined resistance value across at least two contacts in the device connector.

14. The electronic device defined in claim 13 wherein the second circuit comprises circuitry configured to perform Joint Test Action Group test operations.

15. The electronic device defined in claim 14 wherein the first circuit comprises an audio circuit.

16. A method, comprising:
coupling a reversible connector of a tester to a device connector of an electronic device in an orientation selected from: a normal orientation and a reversed orientation in which the reversible connector is rotated 180° with respect to the normal orientation, wherein the electronic device has first and second circuits coupled to the device connector through switching circuitry, and wherein the second circuit is configured to perform testing operations in a test mode; and
applying at least one signal to the device connector from the tester through the reversible connector that directs the electronic device to adjust the switching circuitry to route signals from the connector to the second circuit.

17. The method defined in claim 16 further comprising:
detecting the at least one signal using monitoring circuitry in the electronic device, wherein applying the signal from the tester comprises applying the signal to the device connector through the reversible connector when the reversible connector is connected to the device connector in the reversed orientation.

18. The method defined in claim 17 wherein applying the at least one signal comprises applying a pattern of at least two different voltages to at least two contacts in the reversible connector.

19. The method defined in claim 17 wherein applying the at least one signal comprises applying at least one resistance across at least one pair of contacts in the device connector.

20. The method defined in claim 17 wherein the test mode comprises a Joint Test Action Group test mode, the method further comprising performing Joint Test Action Group testing operations in the test mode in response to detection of the at least one signal.

21. A test system, comprising:
a tester having a reversible connector with at least two contacts surrounded by a ground; and
an electronic device having an audio circuit and a controller that is configured to implement Joint Test Action Group testing during a test mode, wherein the electronic device comprises a device connector, wherein the electronic device has switching circuitry coupled between the audio circuit, the controller, and the device connector, and wherein the device connector has contacts surrounded by a ground, wherein the device connector and the reversible connector are configured to mate in both a normal orientation and a reversed orientation in which the reversible connector is rotated 180° with respect to the normal orientation.

22. The test system defined in claim 21 wherein the switching circuitry is configured to route signals from the device connector to the audio circuit during normal operation and is configured to route signals from the device connector to the controller during the test mode.

23. The test system defined in claim 22 wherein there are six of the contacts and wherein the ground of the device connector surrounds no more contacts than the six contacts.
